(19) United States
(12) Patent Application Publication
(10) Pub. No.: US 2019/0237295 A1
(43) Pub. Date: Aug. 1, 2019

(54) Transmission Electron Microscope Sample Holder

(71) Applicant: Brookhaven Science Associates, LLC, Upton, NY (US)

(72) Inventors: Fernando Enrique Camino, Port Jefferson Station, NY (US); Myung-Geun Han, Stony Brook, NY (US); Dong Su, Shoreham, NY (US); Eric Stach, Swarthmore, PA (US); Paulo Castillo, Melville, NY (US); Ming Lu, Stony Brook, NY (US)

(21) Appl. No.: 16/257,433

(22) Filed: Jan. 25, 2019

Related U.S. Application Data
(60) Provisional application No. 62/622,347, filed on Jan. 26, 2018.

(51) Int. Cl. H01J 37/20; H01J 37/26

(52) U.S. Cl. CPC H01J 37/20; H01J 37/26

(57) ABSTRACT

Embodiments of the invention provide for an electron microscope sample holder, which includes a membrane, a support frame partially surrounding a perimeter or circumference of the membrane, a mounting area for mounting a sample to the membrane, where the mounting area abuts a perimeter or circumference of the membrane not surrounded by the support frame, at least two of conducting contact pads mounted on a the support frame, and at least one electrode lead mounted on the membrane and in electric contact with at least one conducting contact pad.

### CROSS-REFERENCE TO RELATED APPLICATION

This application claims the benefit of U.S. Provisional Application No. 62/622,347, filed on Jan. 26, 2018, which is hereby incorporated by reference in its entirety.

### STATEMENT OF GOVERNMENT RIGHTS

This invention was made with Government support under contract number DE-SC0012704 awarded by the U.S. Department of Energy. The Government has certain rights in the invention.

### FIELD OF THE INVENTION

This disclosure relates generally to specimen mounts for use with transmission electron microscopes, and more particularly to specimen mounts for in-operando electrical measurements.

### BACKGROUND

Understanding the relationship between the properties and the structures of materials is the basis for development of new and better materials for next generation energy technologies. Transmission electron microscopy (TEM) has been indispensable for this development by providing detailed structural motifs down to the atomic scale of the materials. However, great details of atomic structure obtained by state-of-the-art electron microscopy may not always be the property-dictating atomic structures. In those cases the atomic structures are not enough to predict or understand emergent behaviors and properties in advanced materials systems. In order to directly probe the property-dictating structural motifs, it may be necessary to directly correlate electron microscopy data with local properties measured from TEM samples under external stimuli, such as, for example, electric/magnetic fields, photo excitation, temperature, or mechanical strain. In order to observe atomic structures in response to an electric bias, holder chips that provide an electrical bias to the samples have been developed.

FIG. 1 depicts a typical electrical biasing transmission electron microscope (TEM) holder chip 10. The biasing TEM holder chip 10 allows in-operando electrical measurements of a sample 40. The sample 40 is placed over an aperture located approximately at the center of a membrane 25 of the chip 10. The membrane 25 is surrounded by a frame 15. Distributed across the frame 15 are contact pads 20. When the holder chip 10 is placed on a sample probe in the TEM, the contact pads 20 connect electrically with electric contacts on the sample probe. After sample 40 has been placed over the aperture, an electric lead 30 may deposited from the contact pads 20 to the sample 40 using ion bean assisted deposition of metal compound (usually platinum).

Because the current specimen mounts locate the samples approximately at the center of the chip. The conventional specimen mounts require multiple preparation steps which can result in damage and contamination of the sample. Furthermore, the location of the sample on the specimen mount may make it difficult to manipulate or clean the sample after mounting it onto the chip.

### SUMMARY

Embodiments of the invention provide for an electron microscope sample holder, which includes a membrane, a support frame partially surrounding a perimeter or a circumference of the membrane, a mounting area for mounting a sample to the membrane, where the mounting area abuts a perimeter or a circumference of the membrane not surrounded by the support frame, at least two of conducting contact pads mounted on a the support frame, and at least one electrode lead mounted on the membrane and in electric contact with at least one conducting contact pad.

The embodiments provide for the ability to perform FIB sample cleaning after mounting the sample on the sample holder and after connecting sample and chip electrodes. There is no need to detach the sample from the holder for additional cleaning steps if TEM experiments indicate it is required.

The embodiments are compatible with post-FIB, low energy ion cleaning processes (e.g., using a NanoMill system).

The embodiments allow for the mounting of a thick sample on the chip, prior to thinning it down to electron transparency thickness, thus reducing considerably the chance of damaging the sample.

The embodiments reduce number of steps required to mount TEM-ready samples on electrical biasing chips, thus minimizing the chances of sample damage.

The embodiments allow cleaning the sample after electrode definition via electron or ion assisted deposition of platinum (or other metal) compound, thus allowing the removal of contamination originated by this process.

Because the sample is only attached at one edge to the embodied holders, capacitance and leakage current effects are reduced.

FIB cleaning of mounted samples does not affect the mechanical stability of the chip's dielectric membrane, nor interferes with the physical integrity of the electrical contacts between sample and chip.

### BRIEF DESCRIPTION OF THE DRAWINGS

FIG. 1 depicts a prior art electrical biasing transmission electron microscope (TEM) holder chip.

FIG. 2 schematically illustrates an embodiment of a biasing TEM holder chip.

FIG. 3 schematically illustrates another embodiment of a biasing TEM holder chip.

FIG. 4 schematically illustrates another embodiment of a biasing TEM holder chip.

### DETAILED DESCRIPTION

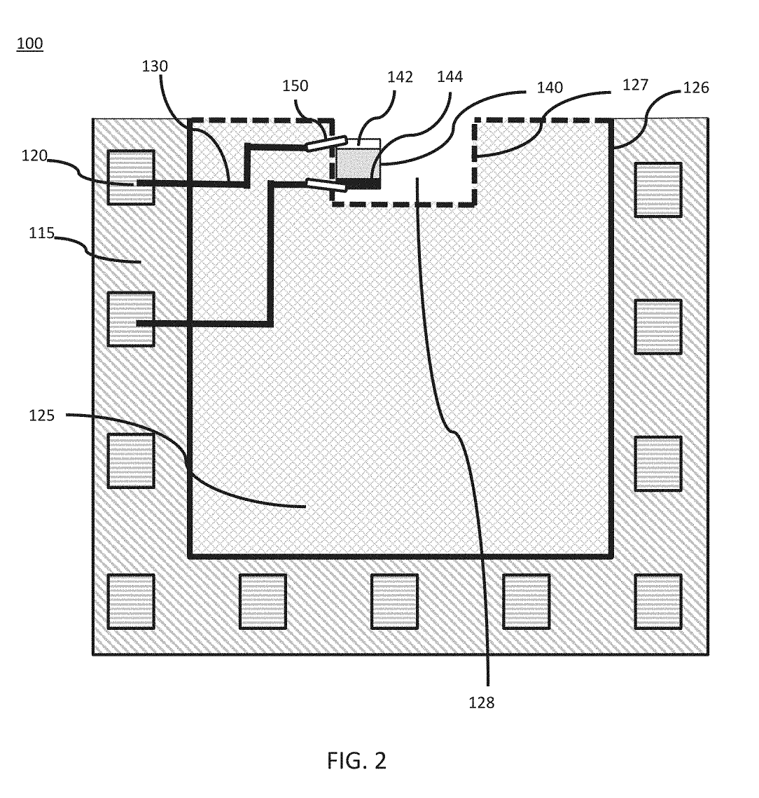

FIGS. 2, 3, and 4 schematically illustrates various embodiments of a biasing TEM holder chips 100, 200, and 300 respectively (Figures are not to scale, and individual elements shown may not be to scale with other elements in the figures). The biasing TEM holder chips 100, 200, and 300 include a membrane 125 which is partially surrounded by a frame 115 along a first partial membrane perimeter or circumference 126. In the case of the perimeter, one edge of the membrane 125 is not surrounded by the frame 115. A second partial membrane perimeter or circumference 127 is marked with dashed lines, and in the case of the perimeter is the edge of membrane 125 not in contact with the frame 115.

The sample 140 is placed and secured adjacent to the membrane 125 in a mounting area 128. The mounting area 128 abuts the second partial membrane perimeter or circumference 127. Distributed across the frame 115 are contact pads 120 (only one is labeled for simplicity). When the holder chips 100, 200, and 300 are placed on a sample probe in the TEM, the contact pads 120 connect electrically with electric contacts on the sample probe. At least one electrode lead 130 is situated on the membrane 125 (only two electrode leads shown, and only one is labeled for simplicity). The electrode lead 130 connects the contact 120 electrically with the mounting area 128. Although only two electrode leads 130 are shown in FIGS. 2-4, each contact pad 120 may have electrode leads 130 connecting the contact pads 120 with the mounting area 128. The electrode leads 130 may come prefabricated onto the biasing TEM holder chips 100, 200, and 300, or may be deposited using for example ion bean assisted deposition of a metal compound before the sample 140 is mounted to the mounting area 128.

After the sample 140 is placed and secured adjacent to the membrane 125 in the mounting area 128, interconnects 150 may deposited from the electrode leads 130 to sample electrodes 142 and 144. The interconnects may be deposited using, for example, ion bean assisted deposition of a metal compound (usually platinum).

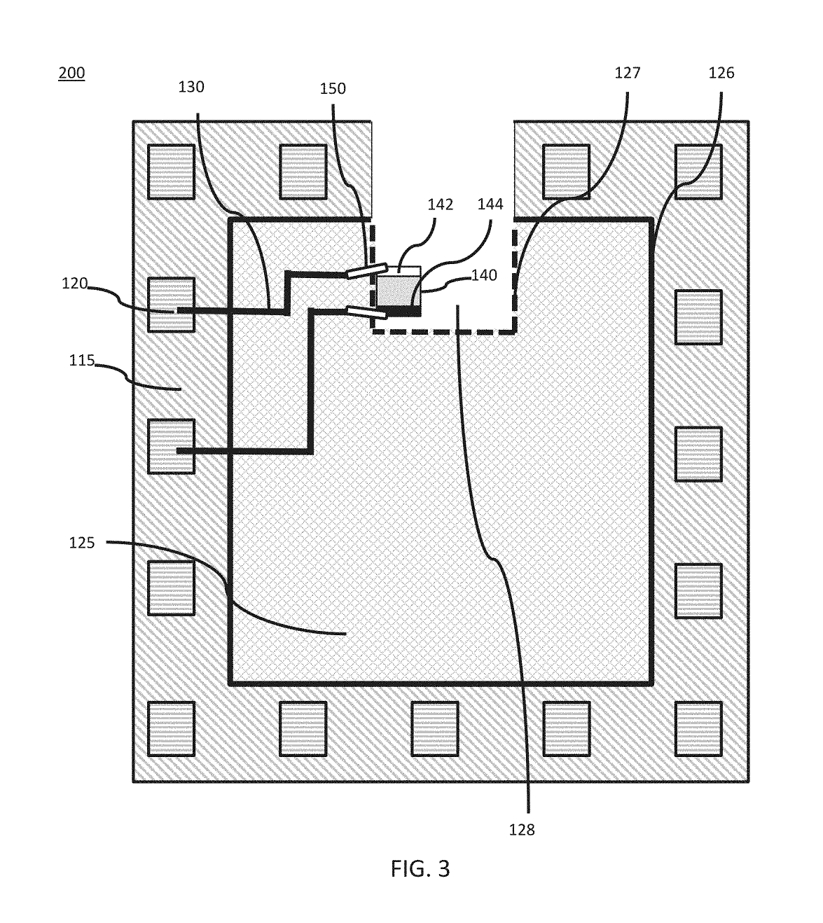

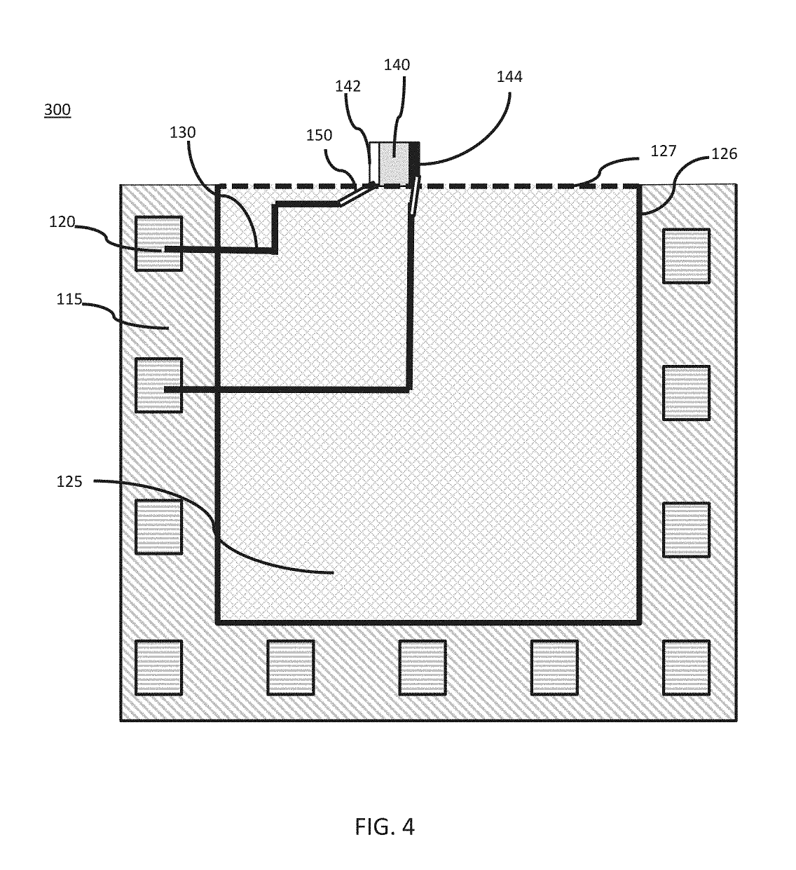

In FIG. 2, the frame 115 surrounds the membrane 125 along three edges of the perimeter of the membrane 125. Furthermore, the mounting area 128 is in an indentation or cut-off in the membrane 125. This indentation may shield the sample 140 in the TEM. In FIG. 3, it can be seen that frame 115 also is adjacent to the fourth edge of the perimeter of the membrane 125, except where the second partial membrane perimeter (or circumference) 127 and the mounting area 128 are located. This extra frame may provide physical support and extra contact pads 120 if needed. FIG. 4 shows an embodiment where there is no indentation or cut-off in the membrane 125, and the second partial membrane perimeter (or circumference) 127 runs along the entire edge of the fourth side of the membrane 125. Multiple mounting areas 128 may be located along the second partial membrane perimeter or circumference 127, allowing for the mounting of several samples 140.

The membrane 125 may be made out of any suitable material and which is well-known in the art. In one embodiment the membrane material is silicon nitride (Si₃N₄). The frame 115 may be made out of any suitable material and which is well-known in the art. In one embodiment the frame material is silicon (Si).

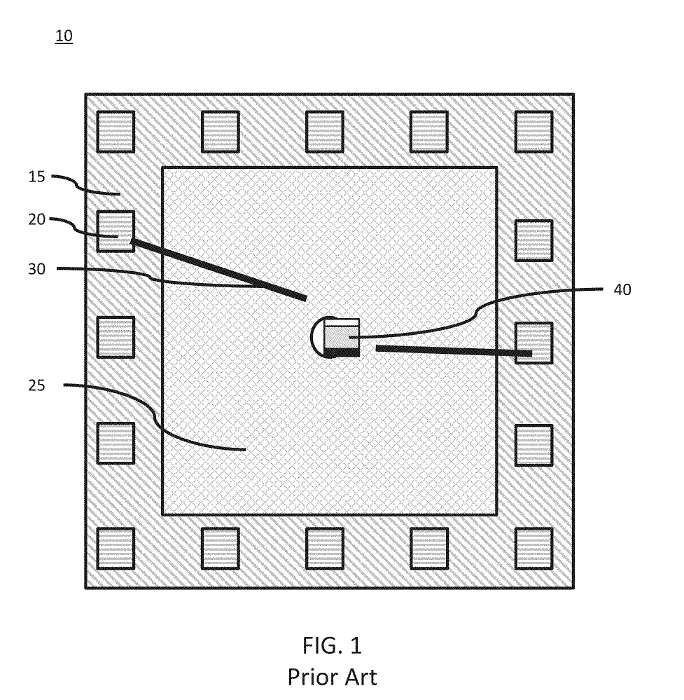

The embodiments disclosed herein avoids a drawback of conventional TEM chips which is that, once mounted, samples cannot be further thinned or cleaned. It is common to mount a sample on a chip, perform a TEM study and find out that the quality of the experiment is hindered due to sample contamination, damage, or excessive sample thickness issues. These problems may remediated if there existed a simple way to perform further cleaning on the sample. The impracticality of cleaning mounted samples on conventional chips is due to the fact that samples are placed parallel to the chip surface and at a large distance away from the edges of the chip (FIG. 1). This geometry does not allow an operator to focus the ion beam on the sample for cleaning. Even if focusing would be possible, assuming that some TEM chips place the sample closer to an edge, it would be impossible to perform proper sample cleaning, as the ion beam would have access to only one side of the sample (the other side being covered by the surface of the chip). To properly clean a sample in a conventional chip, the operator preparing the sample would need: a) unmount the sample from the chip, b) mount it on a separate sample holder, c) clean the sample, d) remount it on the chip, and e) reconnect sample and chip electrodes. It is very likely to damage the delicate sample during this multi-step procedure.

Furthermore, the embodiments disclosed herein avoids the need for multiple sample preparation steps. The placement of focused ion beam (FIB) technique lift-out samples on conventional chips involves multiple steps which increase the chances of losing or damaging the sample. These steps are:
1. Use a micromanipulator probe to transfer the sample onto a special grid to allow FIB thinning.
2. Perform FIB thinning of the sample to electron transparency.
3. Remove the sample from the grid and attach it back on the micromanipulator probe.
4. Move the sample over an aperture on the chip, carefully attach the sample on the chip and disconnect the micromanipulator probe.
5. Connect sample and chip electrodes using ion bean assisted deposition of metal compound (usually platinum).

Furthermore, the embodiments disclosed herein may help avoid the risk of damaging samples when transferring them onto a chip. In conventional chips, samples need to be pre-thinned to thicknesses of about 50 nm before being placed on the chip. Hence, there is considerable risk of damaging the delicate samples during this procedure. The embodiments disclosed herein also reduce the risk of contaminating samples during electrode definition. After a successful placement of a sample on an aperture on the chip, the operator connects sample electrodes to predefined electrodes on the chip. This procedure uses electron or ion beam assisted deposition of a metal compound, which involves the possibility of contaminating the region of interest on the sample.

Additionally the embodiments disclosed herein may reduce limited electrical performance due to stray capacitance and current leakage problems. Conventional TEM sample holders place samples against a thin insulating dielectric membrane, which may add a considerable and unwanted capacitance to the system under study (sample). In addition, leakage current increases in this configuration, limiting the available range of voltage or electric field that can be applied on the sample.

The embodiments disclosed herein include chips fabricated with predefined electrodes, on which an operator can mount thick FIB lift-out samples in a flag-style fashion. This leaves both sides of the sample available for FIB thinning. Using the chips disclosed herein may involve the following simple sample fabrication steps:
1. Mount sample on chip in a flag style fashion. Since samples are mounted after a conventional FIB lift-out procedure, the samples are thick and robust, making the mounting procedure simple and with minimum chance of damage to the sample.
2. Connect sample and chip electrodes. Electrode definition is done prior to sample FIB thinning (next step), thus, any contamination of the sample during the beam assisted deposition of metal may be removed during the subsequent sample cleaning step.
3. Sample FIB thinning to electron transparency.

The chips embodied herein require just one step of sample transfer, from lift-out to the TEM chip, compared to the three transfer steps required in conventional chips (from lift-out to thinning grid, from thinning grid to manipulator probe, and from probe to chip). As used herein with respect to the present sample holder, “thick” corresponds to thicknesses on the order of a few microns (1 μm-5 μm, μm=micrometer). Whereas, “thin” as used herein corresponds to thicknesses that are transparent to an electron beam which is about 100 nm (nm=nanometer) or less. Reducing the amount of transfer steps is beneficial as each of these transfer steps involves some chance of destroying the sample.

Furthermore, the embodied chips allow for further processing of the sample after being mounted. If a TEM experiments indicate the need of additional sample cleaning, an operator can just load the chip in a FIB system and proceed with the cleaning without the need to remove the sample from the chip. In contrast, performing additional sample cleaning in conventional chips involves five steps, namely: a) unmount sample from chip, b) mount sample on thinning grid, c) clean the sample, d) remount sample on chip, and e) reconnect sample and chip electrodes. The delicate, electron-transparent sample has a high chance of breaking during this multi-step procedure.

Embodiments of the present electron microscope sample holder described herein may include a support frame, a membrane that has a perimeter partially surrounded by the support frame and a perimeter partially not surrounded by the support frame, a plurality of sample mounting areas with at least one of the sample mounting areas abutting the perimeter partially not surrounded by the support frame, a plurality of conducting contact pads mounted on a the support frame, and at least one electrode lead mounted on the membrane and in electric contact with at least one conducting contact pad.

The present electron microscope sample holder may also include the perimeter partially not surrounded comprising an indentation. And, the sample mounting area may be situated in the indentation. Further, the perimeter of the present electron microscope sample holder may be a circumference.

In one embodiment the sample holder may have a perimeter, and the membrane of the electron microscope sample holder may have a plurality of edges that are partially surrounded by the support frame, and at least one edge that is partially not surrounded by the support frame. The perimeter partially not surrounded by the support frame may comprise an indentation. And the sample mounting area may be situated in the indentation. Further the indentation may be curved or may have a plurality of edges.

In another embodiment, the sample holder may have a membrane with four edges. The four edges may form the perimeter where three of the four edges are partially surrounded by the support frame, and one of the four edges is partially not surrounded by the support frame. The one edge that is partially not surrounded by the support frame may have an indentation. And the sample mounting area may be situated in the indentation.

It will be appreciated by persons skilled in the art that the embodiments of the present sample holder are not limited to what has been particularly shown and described in the specification. Rather, the scope of the present sample holder is defined by the claims which follow. It should further be understood that the above description is only representative of illustrative examples of embodiments. For the reader's convenience, the above description has focused on a representative sample of possible embodiments, a sample that teaches the principles of the present invention. Other embodiments may result from a different combination of portions of different embodiments.

The specification has not attempted to exhaustively enumerate all possible variations. That alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent. Furthermore, all references, publications, U.S. Patents, and U.S. Patent Application Publications cited throughout this specification are hereby incorporated by reference in their entireties as if fully set forth in this specification.

1. An electron microscope sample holder, comprising:
a support frame;
a membrane, wherein the membrane has a perimeter partially surrounded by the support frame and a perimeter partially not surrounded by the support frame;
a plurality of sample mounting areas, wherein at least one of the sample mounting areas abuts the perimeter partially not surrounded by the support frame;
a plurality of conducting contact pads mounted on the support frame; and
at least one electrode lead mounted on the membrane and in electric contact with at least one conducting contact pad.

2. The electron microscope sample holder of claim 1, wherein the perimeter partially not surrounded comprises an indentation and the sample mounting area is in the indentation.

3. The electron microscope sample holder of claim 1, wherein the perimeter is a circumference.

4. The electron microscope sample holder of claim 1, wherein the membrane has a plurality of edges that are the perimeter partially surrounded by the support frame and at least one edge that is the perimeter partially not surrounded by the support frame, wherein the perimeter partially not surrounded by the support frame comprises an indentation, and the sample mounting area is in the indentation.

5. The electron microscope sample holder of claim 1, wherein the membrane has four edges, the perimeter partially surrounded is three of the four edges, and the perimeter partially not surrounded is one of the four edges, wherein the perimeter partially not surrounded comprises an indentation, and the sample mounting area is in the indentation.

6. An electron microscope sample holder, comprising:
a membrane;
a support frame partially surrounding a circumference of the membrane;
a sample mounting area, wherein the sample mounting area abuts a circumference of the membrane not surrounded by the support frame;
a plurality of conducting contact pads mounted on the support frame; and
at least one electrode lead mounted on the membrane and in electric contact with at least one conducting contact pad.

7. A method for preparing a sample for electrical biasing transmission electron microscopy, comprising:
mounting the sample on a sample mounting area of an electron microscope sample holder;
connecting the sample to an electrode lead on a membrane of the electron microscope sample holder; and
thinning the sample to electron transparency while the sample is mounted to the electron microscope sample holder.

8. The method of claim 7, further comprising, cleaning while the sample is mounted to the electron microscope sample holder.
